(19) United States
(12) Patent Application Publication
(10) Pub. No.: US 2023/0313480 A1
(43) Pub. Date: Oct. 5, 2023

(54) DETERIORATION MODELS DEVELOPMENT METHOD FOR OFFSHORE JACKET-TYPE PLATFORMS

(71) Applicant: Florida Atlantic University Board of Trustees, Boca Raton, FL (US)

(72) Inventors: Ishwarya SRIKANTH, Boca Raton, FL (US); Madasamy AROCKIASAMY, Boca Raton, FL (US)

(21) Appl. No.: 18/168,687

(22) Filed: Feb. 14, 2023

Related U.S. Application Data
(60) Provisional application No. 63/310,185, filed on Feb. 15, 2022.

(51) Int. Cl. E02B 17/00

(52) U.S. Cl. CPC E02B 17/0034; E02B 2017/0056

(57) ABSTRACT

Methods of determining an offshore jacket platform’s condition including determining a geometry, a plurality of loads, and a material composition of an offshore jacket platform; obtaining a base shear at collapse when the offshore jacket platform is intact; calculating a residual resistance factor; determining a criticality factor for each of a plurality of members on the offshore jacket platform; determining a structural health condition state; determining the probability of deterioration; and modeling a rate of deterioration. Another aspect of the disclosure includes methods of determining an offshore jacket platform’s condition in case of lack of inspection records including selecting a corrosion wastage model for splash zones and immersion zones, identifying distribution parameters for the legs and bracings of the jacket platform; determining a structural health condition state for leg and bracing; aggregating probable structural health condition states; and modeling a rate of deterioration of the offshore jacket platform.

### BACKGROUND

### 1. Field of Endeavor

This disclosure relates to a methodology to develop time-dependent deterioration models for preventive maintenance of offshore jacket-type platforms with scarcity of inspection records.

### 2. Description of Related Art

Accurate estimation of offshore jacket platform performance is essential. Past research attempted to understand the effect of ageing and the associated degradation of offshore jacket-type platforms. However, there is still scarcity of published literature in modeling residual service life based on inspection records. Offshore platform maintenance systems are dependent on deterioration models to predict the future performance of structural elements.

Offshore jacket-type platforms are extensively used worldwide to support oil and gas facilities. Most of these existing facilities have served well beyond their expected service life of 25 years and owners are now interested in service life extension of these platforms. Jacket-type platform designs are also utilized to support offshore wind turbines. The robustness of jacket platform design is highly dependent on the maintenance management. Maintenance of these platforms is facilitated thorough knowledge of engineering analysis and predictions of the future condition of steel jacket tubular members. An accurate estimation of offshore structural performance with time-varying effect is necessary to ensure platform structural integrity, perform risk determination, and explore options to extend platform asset life. It is, therefore, essential to develop deterioration models for jacket-type platforms for preventive maintenance and possible service life extension of aging platforms.

Jacket-type platforms are fixed offshore platforms that are used in shallow to medium-deep waters where the water depth may not exceed 500 meters. The inclusion of the assessment procedures and frameworks for existing offshore platforms started in the mid 1990s. In 2014, American Petroleum Institute (API) released a new standard followed by Det Norske Veritas (DNV, 2015) guidelines on the use of probabilistic methods for planning of inspections of offshore structures [1].

Annual periodic inspection of Steel jacket Structures (Underwater) normally includes the following [2]: i) Visual inspection of the structure to locate mechanical damages, possible metallic waste in contact with or in the immediate vicinity of the structure; ii) Visual inspection of type, length and quantity of marine growth on areas pointed out beforehand in different depth levels (photo documentation); iii) Localization of corroded areas (photo documentation); iv) Visual inspection of the anode condition. The inspection shall be comprised of a sufficient representative number of the total number of anodes. The inspection shall also be comprised of potential reading of selected anodes; v) Visual inspection of the seabed for possible erosion or building up of scour (photo documentation); and vi) Implementation of NDT-thickness- measurements on selected spots for reference measurement.

Generally, inspection results are recorded as conditional ratings for each of the structural elements (i.e., legs, bracings, piles, etc.) which are further used in the overall structural safety assessment. Typically, five condition states (CS) are defined in the maintenance of offshore structures: Very good (CS5), Good (CS4), Fair (CS3), Poor (CS2), Very poor (CS1) [3].

A number of researchers have performed reassessment of aging jacket structures for possible service life extension. Ashish et. al. (2017) proposed a framework that provides precise corrosion models, new damage theories, and assessment guidelines to predict the remaining fatigue life and check the structural adequacy in all the limit states during the whole extended service life [1]. Yong Bai et. al. (2016) performed reassessment of jacket structure due to uniform corrosion [4]. However, only limited studies are available on the deterioration modeling of offshore jacket platform members based on inspection records.

All references cited herein are incorporated herein by reference in their entireties.

### SUMMARY

A first aspect of the disclosure accordingly includes a method of determining an offshore jacket platform’s condition including (a) determining the geometry of the offshore jacket platform; (b) determining the offshore jacket platform’s material composition; (c) determining a plurality of loads acting upon the offshore jacket platform; (d) obtaining a base shear at collapse for the offshore jacket platform when the offshore jacket platform is intact, wherein the base shear at collapse is determined from the geometry, the material composition, and the plurality of loads acting upon the offshore jacket platform; (e) calculating a residual resistance factor; (f) determining a criticality factor for each of a plurality of members on the offshore jacket platform; (g) determining a structural health condition state for the offshore jacket platform (h) determining the probability of deterioration of the offshore jacket platform; and (i) modeling a rate of deterioration of the offshore jacket platform.

In certain examples, the plurality of loads includes dead load, wave load, and current load on the offshore jacket platform.

In certain examples, step (d) further includes performing a nonlinear static pushover analysis using variables comprising the geometry, the material composition, and the plurality of loads acting upon the offshore jacket platform.

In certain examples, the residual resistance factor is calculated by dividing the ultimate resistance of the offshore jacket platform with any damage by the ultimate resistance of an undamaged offshore jacket platform.

In certain examples, the criticality factor corresponds to the residual resistance factor and the criticality factor is assigned a value selected from the group consisting of: 1 when the residual resistance factor is less than or equal to 0.2; 0.8 when the residual resistance factor is greater than 0.2 and less than or equal to 0.4; 0.6 when the residual resistance factor is greater than 0.4 and less than or equal to 0.6; 0.4 when the residual resistance factor is greater than 0.6 and less than or equal to 0.8; and 0.2 when the residual resistance factor is greater than 0.8 and less than 1.

In certain examples, the criticality factor is assigned a failure consequence, wherein the failure consequence is selected from the group consisting of: very serious, serious, not serious, local effect, and does not affect, wherein very serious corresponds to a criticality factor of 1, serious corresponds to a criticality factor of 0.8, not serious corresponds to a criticality factor of 0.6, local effect corresponds to a criticality factor of 0.4, and does not affect corresponds to a criticality factor of 0.2.

In certain examples, the probability of deterioration is determined by multiplying a transpose of a transition probability matrix by an initial condition vector of the offshore jacket platform by a vector of at least one structural health condition state.

In certain examples, the rate of deterioration modeling step further comprises using a Markov chain stochastic model.

Another aspect of the disclosure includes a method of determining an offshore jacket platform’s condition including (a) selecting a corrosion wastage model for splash zones and immersion zones; (b) identifying distribution parameters for a remaining thickness of each of a plurality of legs and a plurality of bracings of the offshore jacket platform; (c) determining a structural health condition state for each of a plurality of members on the offshore jacket platform; (d) aggregating probable structural health condition states for a predetermined number of years; and (e) modeling a rate of deterioration of the offshore jacket platform.

In certain examples, the structural health condition state is determined from the remaining thickness of each of the plurality of legs and the plurality of bracings.

In certain examples, the structural health condition state is assigned a value selected from the group consisting of CS5, CS4, CS3, CS2, and CS1; wherein CS5 indicates very good condition of the offshore jacket platform, CS4 indicates good condition of the offshore jacket platform, CS3 indicates fair condition of the offshore jacket platform, CS2 indicates poor condition of the offshore jacket platform, and CS1 indicates very poor condition of the offshore jacket platform.

In certain examples, the predetermined number of years in step (d) is from 1 to 100 years.

In certain examples, step (e) further includes performing a predetermined number of Monte Carlo Simulations.

In certain examples, the predetermined number of Monte Carlo simulations is from 500 to 1,000,000 Monte Carlo simulations.

In certain examples, each Monte Carlo simulation is performed by: defining a plurality of input variables; defining a plurality of parameters; generating random numbers from a probability distribution defined for each input variable; deterministically computing each of a plurality of runs of randomly generated input parameters; and analyzing results to obtain probabilities of different outcomes of deterioration.

In certain examples, the plurality of input variables includes a condition state probability and a vector of at least one condition state.

### BRIEF DESCRIPTION OF SEVERAL VIEWS OF THE DRAWINGS

The invention will be described in conjunction with the following drawings in which like reference numerals designate like elements and wherein:

FIG. 1 is an exploded diagram view of an offshore jacket platform.

FIG. 2 is a diagram of the evolution of jacket platform structural health condition.

FIG. 3 is a flow chart of the methodology for the Markov-chain based model.

FIG. 4 is a flow chart of the methodology for the stochastic-mechanistic deterioration model.

FIG. 5A is a graph of the probability distribution of offshore tubular member thickness for jacket platform legs.

FIG. 5B is a graph of the probability distribution of offshore tubular member thickness for jacket platform bracings.

FIG. 6 is a perspective view of a typical offshore jacket platform.

FIG. 7 is a side view of the elevation of an offshore jacket platform.

FIG. 8 is a graph of the structural health condition state using the Markov-chain based deterioration model for a new offshore jacket platform.

FIG. 9 is a graph of the probability of condition states for a new offshore jacket platform.

FIG. 10 is a perspective diagram of jacket members in various condition states.

FIG. 11 is a graph of the structural health condition state using the Markov-chain based deterioration model for an aging offshore jacket platform.

FIG. 12 is a graph of the probability of condition states for an aging offshore jacket platform.

FIG. 13A is a graph of structural health condition states for offshore tubular legs in a splash zone using a deterioration model.

FIG. 13B is a graph of structural health condition states for offshore tubular legs in a splash zone using time-dependent condition state probabilities.

FIG. 14A is a graph of structural health condition states for offshore tubular bracings in a splash zone using a deterioration model.

FIG. 14B is a graph of structural health condition states for offshore tubular bracings in a splash zone using time-dependent condition state probabilities.

FIG. 15A is a graph of structural health condition states for offshore tubular legs in an immersion zone using a deterioration model.

FIG. 15B is a graph of structural health condition states for offshore tubular legs in an immersion zone using time-dependent condition state probabilities.

FIG. 16A is a graph of structural health condition states for offshore tubular bracings in an immersion zone using a deterioration model.

FIG. 16B is a graph of structural health condition states for offshore tubular bracings in an immersion zone using time-dependent condition state probabilities.

FIG. 17 is a graph of typical SHI values of a new jacket platform.

FIG. 18 is a graph of typical SHI values of an aging jacket platform.

FIG. 19 shows an exemplary Markov chain modeling system including a processing circuit with a processor and a memory.

FIG. 20 shows an exemplary deterioration modeling system including a processing circuit with a processor and a memory.

FIG. 21 is a flow chart of the methodology for predicting and performing maintenance repair, replacement, and rehabilitation actions.

### DETAILED DESCRIPTION

The disclosure presents deterioration models for maintenance planning of offshore jacket platform based on two methods: i) the stochastic Markov-chain based model and ii) the stochastic-mechanistic deterioration models based on steel corrosion rates. The deterioration models disclosed herein facilitate accurate estimation of maintenance, repair, and rehabilitation actions without ongoing monitoring or real-time sensor inputs of a current condition of the offshore jacket platform.

Markov-chain models use the estimation of transition probability matrix (TPM), which is typically derived from the inspection data. The global structural health condition of the jacket is computed based on the condition of individual elements and their criticality in terms of failure consequence. The criticality factors are established based on nonlinear static redundancy analyses. This method can model deterioration when routine inspection records of jacket members are available. When there is scarcity of inspection records, the stochastic-mechanistic deterioration modeling approach can be used. Monte-Carlo simulations with established corrosion wastage models are utilized to estimate the time-dependent deterioration of jacket legs, horizontal bracings, and diagonal bracings in splash and immersion zones. Examples of different types of corrosion wastage models include uniform corrosion and pitting corrosion. Regarding corrosion wastage models, the time-dependent effect of uniform corrosion and pitting corrosion are considered through established corrosion wastage models applicable in splash and immersion zones. This stochastic-mechanistic method is proposed when there is scarcity of inspection records. The deterioration models are further utilized to predict the timing for Maintenance, Repair, and Rehabilitation (MRR) actions and estimate the residual service life of the jacket platform.

The stochastic Markov-chain based model is dependent on the current condition of the platform and the condition transition probabilities which are derived from the inspection records. To overcome the problem of scarcity in the condition records, the disclosure proposes a stochastic-mechanistic deterioration modeling approach based on corrosion wastage models.

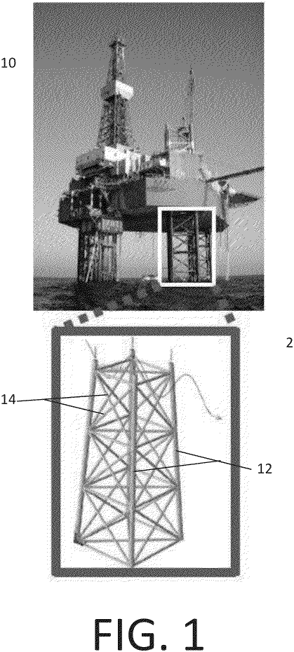

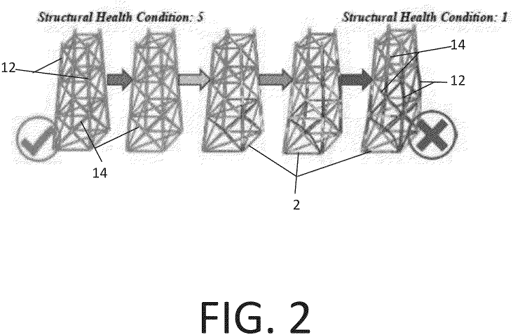

In the exemplary Markov-chain based deterioration model, the structural deterioration process is characterized by the transition probabilities from one condition state to another. The transition probabilities are derived from the inspection records indicating the condition of the jacket members located at various water depths. Based on the inspection records and the criticality of various jacket members, the global structural health of the jacket is derived. The criticality of jacket leg and bracing members are established based on nonlinear static redundancy analysis. The Markov-chain deterioration model and the evolution of condition states of the jacket platform are derived. FIG. 1 shows an exemplary model of a support member 2 of an offshore jacket platform 10 in an exploded view. The support member 2 is supported by a plurality of legs 12 and bracings 14. FIG. 2 illustrates the evolution of a jacket platform support member’s 2 structural health condition during its service life. As shown in FIG. 2, offshore jacket platform support members 2 are assigned a structural health condition ranging from 5 to 1 that describes the structural soundness of the platform and whether the platform needs no repair, minor repair, moderate repair, major repair, or complete replacement. The structural soundness depends on factors including the remaining thickness and strength of the legs 12 and bracings 14 on the platform. Platforms with a structural health condition of 5 are considered in “very good” condition and not in need of repair, whereas platforms with a structural health condition of 1 are considered in “very poor” condition and are in need of complete replacement.

In the stochastic-mechanistic deterioration model, condition state probabilities for jacket legs and bracings in splash and immersion zones are generated using Monte Carlo simulations performed on established corrosion wastage models. Based on the generated condition state probabilities, the deterioration models are developed. In certain examples, the approach is implemented for prioritization of actions and preventive maintenance of offshore jacket platform members in the case of absence of condition state records.

Decisions on MRR actions are obtained based on the Structural Health Index (SHI) derived from the global structural heath condition (C). The foregoing examples highlight the detailed methodology for each of the proposed modeling approaches and their demonstration with the following case study, which demonstrates the application of the exemplary deterioration modeling approaches with a case study of a typical 4-legged offshore jacket platform.

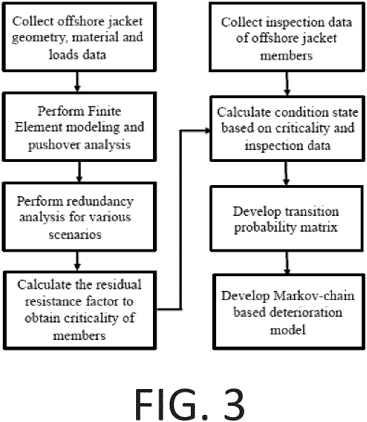

FIG. 3 shows a flow chart of the methodology for the Markov-chain based model. The Markov chain model is a widely applied technique in the performance assessment of deteriorating structures [5]. It uses a large amount of inspection data to establish its transition probability matrix. Using this technique, the change in the structural condition based on the current condition state can be obtained. The structural deterioration process is characterized by the transition probabilities from one condition state to another. The methodology for developing Stochastic Markov-chain based model is shown in the flowchart depicted in FIG. 3. First, the offshore jacket geometrical and material properties, and the loading conditions are obtained for the platform of interest. Then, finite element modeling and nonlinear static (pushover) analysis is performed to obtain the base shear at collapse for the intact structure. This is followed by redundancy analyses for various damage scenarios. In the exemplary study, redundancy analyses are carried out for horizontal bracing, and vertical diagonal bracings. Based on the redundancy analyses, the residual resistance factor is calculated using Equation 1 given by:

$$R e s i d u a l R e s i s t a n c e F a c t o r \left(R\right) = {\text{U}}_{\text{d}} / {U}_{\text{ud}} \qquad \text{(1)}$$

Where, U_{d} is the ultimate resistance of damaged jacket platform and U_{ud} is the ultimate resistance of undamaged platform.

Based on the residual resistance factor obtained for each damage scenario, the criticality of members is obtained. The criticality of members is related to the consequence of failure. For example, a highly critical member such as jacket legs will have a very high consequence of failure when compared to the horizontal bracings. In the exemplary study, the criticality factor for various members is assumed arbitrarily based on the residual resistance factor as shown in Table 1. These limits could be adjusted depending on the expert knowledge.

TABLE 1

CRITICALITY FACTORS

| Failure Consequence | Criteria based on Residual resistance factor | Criticality factor (w) |
|---|---|---|
| Very Serious (A) | 0 < R ≤ 0.2 | 1 |
| Serious (B) | 0.2 < R ≤ 0.4 | 0.8 |
| Not Serious (C) | 0.4 < R ≤ 0.6 | 0.6 |
| Local effect (D) | 0.6 < R ≤ 0.8 | 0.4 |
| Does not affect (E) | 0.8 ≤ R < 1 | 0.2 |

Based on the inspection results of the individual jacket members, the global structural condition (C) is assessed based on the criticality factor and the percentage of structural elements at a given criticality which is given by the following Equation 2:

$${C}_{i = \left(1 , … 5\right)} = \left(\frac{1}{Z {\text{w}}_{\text{k=} \left(\text{A,} … \text{B}\right)}}\right) \times \left({w}_{A} {p}_{A} + ⋯ + {w}_{E} {p}_{E}\right) \qquad \text{(2)}$$

Where p_{A}, p_{B} through p_{E} are the percentages of structural elements with criticality A, B, ..., E respectively that has achieved Condition Cᵢ ₌ ₍₁ _{...} ₅₎. w_{A}, w_{B}, through w_{E} are the criticality factors as shown in Table 1.

The global structural health condition is thus assessed for two consecutive inspection periods to develop the transition probability matrix used for the Markov-chain model. For instance, the newly built structure is normally considered to have the highest grading without any initial damage, which is formulated as C(0) = [1, 0, 0, 0, 0]. Then, the performance of the structure after t time interval of operation is predicted based on the stochastic Markov-chain model, shown in Equation 3 below:

$$C \left(t\right) = {\left[{P}^{T}\right]}^{t} \times C \left(0\right) \times S \qquad \text{(3)}$$

where C(0) is the initial condition vector (i.e., {1, 0, 0, 0, 0} for a new structure), [P^{t}]^{T} is the transpose of TPM [P] at period t, and S is the vector of condition states {5, 4, ..., 1}, with 5 - very good condition to 1-very poor condition.

The general formulation of the TPM is given by Equation 4:

$$P = \left[\begin{matrix}{p}_{55} & {p}_{54} & 0 & 0 & 0 \\ 0 & {p}_{44} & {p}_{43} & 0 & 0 \\ 0 & \text{(4)} 0 & {p}_{33} & {p}_{32} & 0 \\ 0 & 0 & 0 & {p}_{22} & {p}_{21} \\ 0 & 0 & 0 & 0 & {p}_{11}\end{matrix}\right]$$

where p₅₅ denotes the probability of jacket structure which had global structural health condition rating of 5 at a given inspection time stayed in the same condition during the consecutive inspection. It is assumed that the jacket cannot deteriorate to two or more steps within a consecutive inspection period. Hence, these probabilities are 0 in the matrix. p₅₄ denotes the probability of jacket in condition 5 deteriorated to condition 4 within the inspection period (p₅₄= 1 - p₅₅). The inspection period of jacket structures is typically one year. S is the vector of condition rating [5, 4, 3, 2, 1].

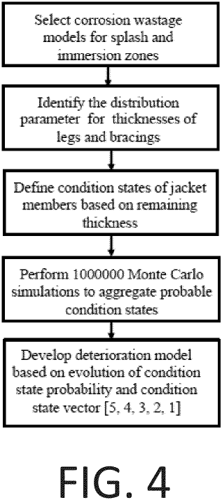

In certain examples, the deterioration of jacket platform members (legs and bracings) is developed from mechanistic corrosion wastage models in case of lack of inspection records [6]. In the present study, corrosion wastage models for uniform corrosion and pitting corrosion are employed and further, the time-dependent condition probabilities of offshore tubular members are derived using Monte Carlo simulations. FIG. 4 shows the methodology for the proposed stochastic-mechanistic deterioration model.

The following examples present the modeling approach and the results including the choice of corrosion model, distribution of model parameters, condition states definition, generation of element condition probabilities through Monte Carlo simulations for each condition state, and development of deterioration models for jacket legs and bracings in both splash and immersion zones.

Regarding choice of corrosion wastage models, corrosion is an important strength degradation phenomenon that is widely encountered in offshore steel structures as a result of a harsh corrosive environment. Typical forms of corrosion that occur in marine environments on steel elements include uniform corrosion, pitting corrosion, crevice corrosion, galvanic corrosion, stress corrosion, and corrosion fatigue [7]. Among the different types of corrosion under offshore environments for jacket platforms, uniform corrosion and pitting corrosion are the most common forms of corrosion. Corrosion is accounted through corrosion wastage models. Corrosion results in the reduction of member thickness and thereby reduction of overall stiffness of the structure. In the exemplary study, the time-dependent effect of uniform corrosion and pitting corrosion are considered through corrosion wastage models applicable in splash and immersion zones [1, 8]. The thickness reduction due to uniform corrosion and pitting corrosion as a function of time can be approximately modeled based on Equation 5.

$${t}_{c} \left(t\right) = A {\left(t - {t}_{p r}\right)}^{B} + α {\left(t - {t}_{p i}\right)}^{β} \qquad \text{(5)}$$

where t_{c}(t) is the thickness wastage in millimeters as a function of time, t is the lifetime of the members, tₚᵣ is the corrosion protection in years, A and B are uniform corrosion wastage model parameters dependent on the inspection findings and type of zone (splash or immersion zones), α and β are parameters for pitting corrosion wastage model, and tₚᵢ is the time for initiation of pitting corrosion.

In the present study, the effect of corrosion protection and the time for pitting corrosion initiation are assumed to be negligible when compared to the life of the members. Hence, Equation 5 could also be written as shown by Equation 6:

$${t}_{c} \left(t\right) = A {\left(t\right)}^{B} + a {\left(t\right)}^{β} \qquad \text{(6)}$$

The mean values of parameters A and B are considered as 0.3 and 1 respectively for splash zone, and 0.1 and 1 for immersion zone based on the study reported by Melchers, 1995 [8]. The mean values of α and β are considered as 0.0028 and 0.3877 respectively [1].

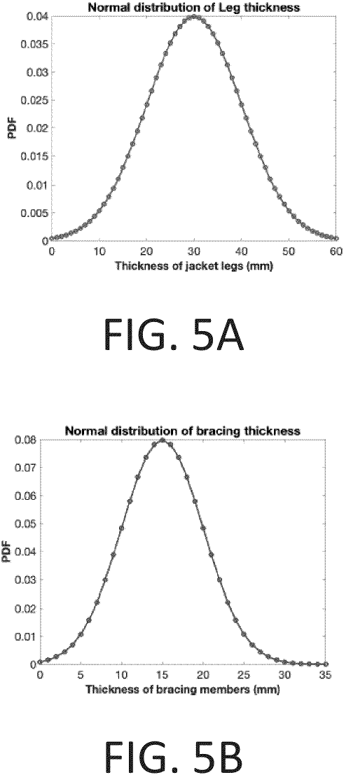

Regarding model parameters, the Condition State (CS) of the offshore jacket members is modeled based on the remaining thickness as a function of age of the members given by the following equation (Equation 7):

$${t}_{r} \left(t\right) = {t}_{i} - {t}_{c} \left(t\right) \qquad \text{(7)}$$

Where tᵣ(t) is the remaining effective thickness of the member in millimeters and tᵢ is the initial thickness of the member in millimeters. In Equation 7, the initial thickness is modeled as a random variable and the other terms are deterministic as presented in Equation 6. The general form of the normal distribution is shown in Equation 8. The initial thickness of the members is assumed to follow a normal distribution as shown in FIGS. 5A and 5B. FIG. 5A is a graph of the probability distribution of offshore tubular member thickness for jacket platform legs and FIG. 5B is a graph of the probability distribution of offshore tubular member thickness for jacket platform bracings. Regarding distribution parameters, the initial thickness of legs and bracings are assumed to follow a normal distribution given by Equations 9 and 10 respectively. The typical mean (µ) and standard deviation (σ) of thickness of legs and bracing members are based on published literature [9]. Table 2 summarizes the distribution of model parameters which are further utilized in Monte-Carlo simulations based on the condition states definition shown in Table 3.

$${f}_{1} \left({t}_{i} \left|μ , σ\right)\right) = \frac{1}{a \times \sqrt{2 n}} \times {e}^{\frac{{\left(x - μ\right)}^{2}}{2 \times {a}^{2}}} \qquad \text{(8)}$$

$${f}_{1} \left({t}_{i} \left|30 , 10\right)\right) = \frac{1}{10 \times \sqrt{2 n}} \times {e}^{\frac{{\left(x - 30\right)}^{2}}{2 \times {10}^{2}}} \qquad \text{(9)}$$

$${f}_{b} \left({t}_{1} \left|15 , 5\right)\right) = \frac{1}{5 \sqrt{2 n}} \times {e}^{\frac{{\left(x - 15\right)}^{2}}{2 \times {5}^{2}}} \qquad \text{(10)}$$

TABLE 2

DESCRIPTION OF MODEL PARAMETERS

| Variable | Type | Variable/Parameter value |
|---|---|---|
| tᵢ | Random- Normally distributed | µ=30, σ = 10 (legs) µ=15, σ = 5 (bracings) |
| t | Deterministic | [1, 50] |
| A, B | Deterministic | 0.3, 1 (splash zone) 0.1, 1 (immersion zone) |
| α, β | Deterministic | 0.0028, 0.3877 |

The health of the platform members is inspected and generally recorded as condition states. Five condition states are typically defined in the maintenance of offshore structures with 5-very good to 1-very poor condition. In the present study, condition states of tubular members are defined based on the remaining thickness as a function of age as shown in Table 3. The remaining effective thickness with respect to initial thickness of the members is given as a ratio tᵣ/tᵢ. The definition of the criteria for each condition state is subjective and could be adjusted based on expert judgement.

TABLE 3

CONDITION STATES DEFINITION

| | | |
|---|---|---|
| Condition State (CS) | Description | Criteria |
| CS5 | Very Good | 0.95 < tr/tᵢ ≤ 1 |
| CS4 | Good | 0.85 < tr/tᵢ ≤ 0.95 |
| CS3 | Fair | 0.7 < tr/tᵢ ≤ 0.85 |
| CS2 | Poor | 0.5 < tr/tᵢ ≤ 0.7 |
| CS1 | Very Poor | 0 ≤ tr/ti ≤ 0.5 |

The deterioration model is developed using Monte Carlo simulation techniques. The concept of Monte Carlo simulation includes the: i) definition of input variables and parameters; ii) generation of random numbers from the probability distribution defined for each input variable; iii) deterministic computation for each run of randomly generated input parameters; and iv) analysis of results to obtain probabilities of different outcomes.

In the exemplary study, 10⁶ Monte Carlo simulations are performed to generate one million samples of condition state for each year starting from 1 through 100 years with an interval of one year, based on the defined criteria shown in Table 3. The probability of occurrence of each condition state is then aggregated for all the years which is further utilized to develop the deterioration model. The deterioration of leg and bracings could be obtained from the condition state probabilities by using the following equation (Equation 11):

$$C S \left(t\right) = \left[{p}_{i} \left(t\right)\right] \left[C S\right] \qquad \text{(11)}$$

Where, CS(t) is the condition state as a function of time, [pᵢ(t)] is the probabilities generated as a function of time for each condition state {5, 4, 3, 2, 1}, [CS] is the vector of condition states [5, 4, 3, 2, 1].

The disclosure will be illustrated in more detail with reference to the following Examples, but it should be understood that the present disclosure is not deemed to be limited thereto.

### EXAMPLES

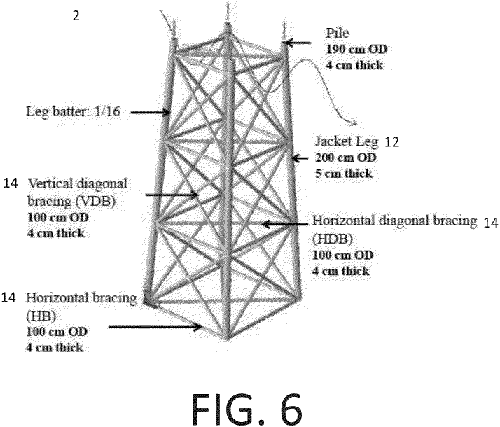

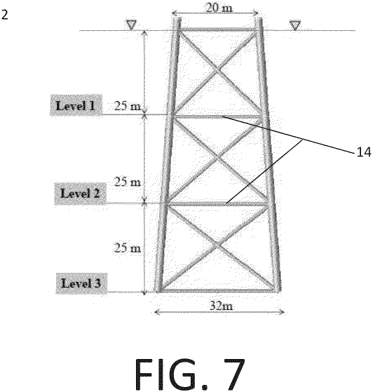

Using an exemplary case study of a typical offshore jacket platform for residual service life estimations, the structure adopted in the case study is a 4-legged offshore jacket platform located at a water depth of 75 meters. It has three bays, with each 25 m deep. The dimension at the top is 20 m by 20 m in plan and that at the base is 32 m by 32 m. The jacket legs are battered at 1 to 16 (horizontal to vertical) in both broad side and end on framing [10-12]. The jacket platform is designed based on the American Petroleum Institute (API), Det Norske Veritas (DNV), and NORSOK standards [13-15]. Dead load, wave, and current loads are considered in the analyses. The effect of wind on the deck is neglected for simplicity. Dead loads comprise of the self-weight of jacket and the load from topsides (or deck) acting as equivalent concentrated vertical loads on the piles. A total load of 46,800 kN from the topsides is considered in the modeling. The model interacts with the offshore environment represented as Stoke’s fifth order equation. The maximum directional wave heights for the 1-year return period is considered as 12.8 meters with a wave period 13.8 seconds. Surface current velocity is considered as 1 m/s. The total lateral load due to wave and current loads is 2,939 kN. FIG. 6 shows the jacket platform support member 3-D model with its member dimensions. As shown, the support member 2 includes a plurality of legs 12 and bracings 14. The bracings 14 may include horizontal bracings, horizontal diagonal bracings, and vertical diagonal bracings. In this particular example, the legs 12 measure 200 cm in thickness, whereas the bracings 14 measure 100 cm in thickness. The elevation of the jacket platform support member 2 is shown in FIG. 7, wherein each section of the jacket platform support member 2 is defined by the location of the horizontal bracing 14. In this particular example, there are 25 m between each jacket horizontal bracing 14 and four horizontal bracings, leading to three sections and a jacket support member 2 height of 75 m.

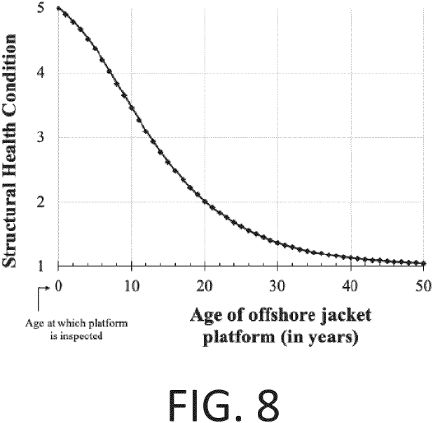

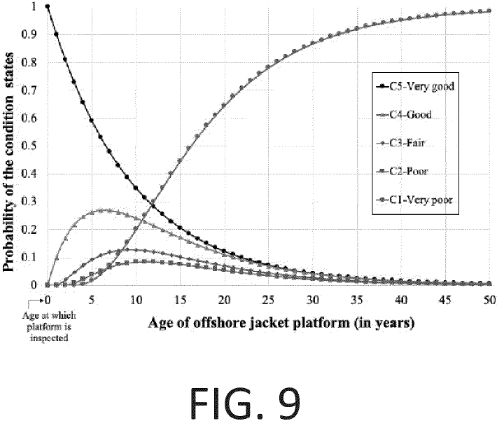

Regarding the exemplary Stochastic Markov-chain based deterioration model, nonlinear static (or pushover) analyses for various damage scenarios are performed on the jacket platform [6]. Based on the nonlinear static redundancy analyses, the residual resistance factors are computed as per Equation 1, and the criticality factors of the members are assigned as shown in Table 1. Table 4 shows the base shear at collapse for various cases and their corresponding residual resistance factors. The damage scenario cases are characterized by the removal of members. For example, when vertical diagonal bracings at Level 1 (VDB1) are removed from the platform and a pushover analysis is performed, the criticality factors are assigned based on the residual resistance factors as shown in Table 1. Based on the criticality factors and the inspection records of the jacket members, the global structural health condition (C) can be computed. The global structural condition shows the percentage of various members in different condition states weighted by their criticality (i.e., the consequence of failure) as shown in Equation 2. The jacket legs are highly critical members for structural integrity and hence the criticality factor is always considered as 1. Using the global structural condition computed for two consecutive inspections, the elements of the TPM are computed. In case of availability of inspection records for several consecutive years, the average of transition probabilities is considered in the TPM. FIG. 8 shows the global structural deterioration for a new platform based on a typical TPM as shown in Equation 11. The initial condition C(0) of the new platform is {1, 0, 0, 0, 0}, meaning that the global structural health condition is 100%, or in very good condition. The evolution of condition states for the deterioration model is shown in FIG. 9. It is observed that the jacket reaches a poor condition in 20 years, under routine maintenance.

TABLE 4

RESIDUAL RESISTANCE AND CRITICALITY FACTORS BASED ON REDUNDANCY ANALYSES

| Case No. | Member group removed | Base shear at collapse (kN) | Residual resistance factor (R) | Criticality factor (w) |
|---|---|---|---|---|
| 0 | None | 94349 | 1.000 | --- |
| 1 | VDB1 | 45611 | 0.483 | 0.6 |
| 2 | VDB2 | 38786 | 0.411 | 0.6 |
| 3 | VDB3 | 31466 | 0.334 | 0.8 |
| 4 | HDB1 | 94153 | 0.998 | 0.2 |
| 5 | HDB2 | 94333 | 1.000 | 0.2 |
| 6 | HDB3 | 87626 | 0.929 | 0.2 |
| 7 | HB1 | 94302 | 1.000 | 0.2 |
| 8 | HB2 | 92930 | 0.985 | 0.2 |
| 9 | HB3 | 81439 | 0.863 | 0.2 |

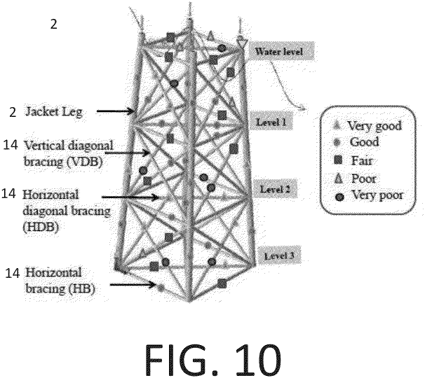

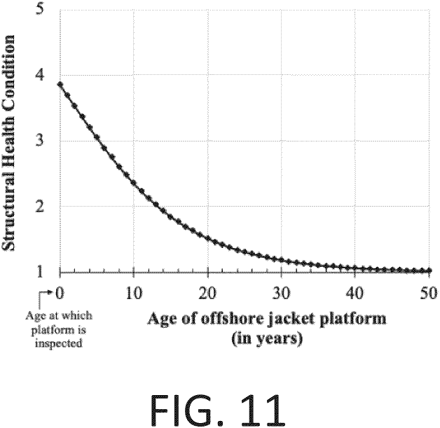

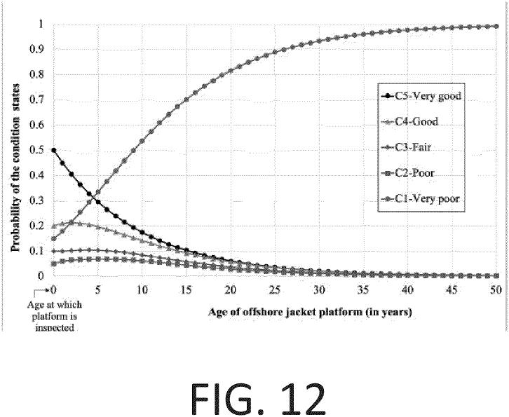

In the case of an aging platform, the initial inspected condition of various jacket members 2 could be different, as shown in FIG. 10, leading to a global structural health condition with varying percentages of condition states. The diagram shown in FIG. 10 shows a triangle without an outline as showing the condition of the particular component of the jacket member as “very good,” a circle without an outline as “good,” a square as “fair,” a triangle with an outline as “poor,” and a circle with an outline as “very poor” conditions. Therefore, it is possible for a bracing 14 to be in “very poor” condition while a leg 12 is in “good” condition. For further example, the initial condition C(0) of an aging platform at 8 years is considered as {0.5, 0.2, 0.1, 0.05, 0.15}. Based on this initial condition and the TPM shown in Equation 12 below, the deterioration model of an aging offshore jacket platform is developed as shown in FIG. 11. It is observed that the platform reaches a poor condition in 13 years, under routine inspection and maintenance. The evolution of various condition states of an aging platform is shown in FIG. 12.

$$P = \left[\begin{matrix}0.9 & 0.1 & 0 & 0 & 0 \\ 0 & 0.8 & 0.2 & 0 & 0 \\ 0 & 0 & 0.6 & 0.4 & 0 \\ 0 & 0 & 0 & 0.4 & 0.6 \\ 0 & 0 & 0 & 0 & 1\end{matrix}\right] \qquad \text{(12)}$$

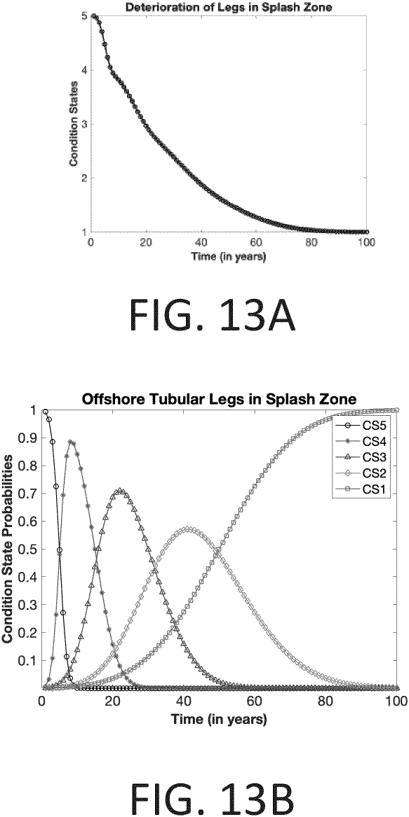

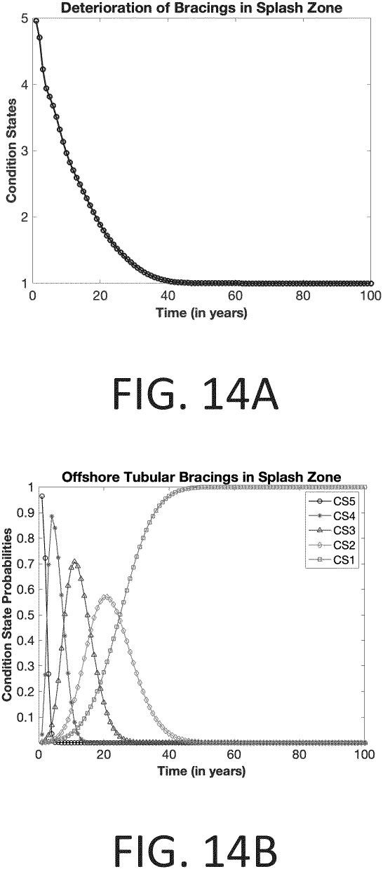

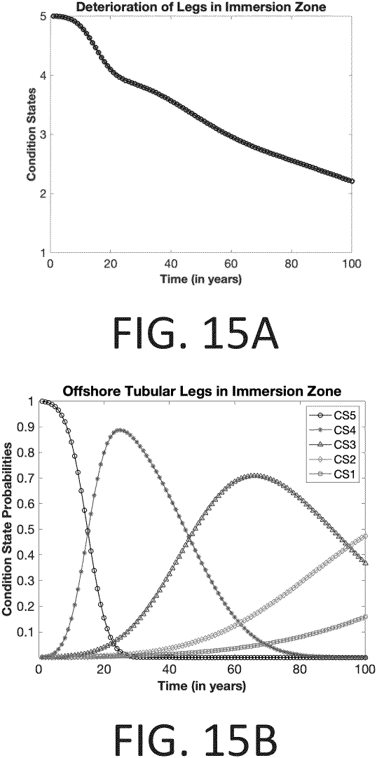

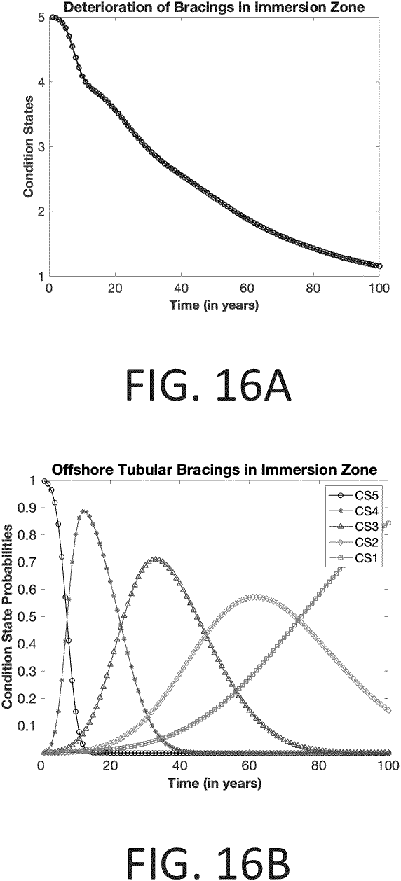

Based on the exemplary stochastic-mechanistic deterioration modeling approach, the deterioration models for offshore jacket members are developed. FIGS. 13-16 show the deterioration models and the evolution of condition states for legs and bracings in both splash and immersion zones. FIG. 13A is a graph of structural health condition states for offshore tubular legs in a splash zone using a deterioration model. FIG. 13B is a graph of structural health condition states for offshore tubular legs in a splash zone using time-dependent condition state probabilities. FIG. 14A is a graph of structural health condition states for offshore tubular bracings in a splash zone using a deterioration model. FIG. 14B is a graph of structural health condition states for offshore tubular bracings in a splash zone using time-dependent condition state probabilities. FIG. 15A is a graph of structural health condition states for offshore tubular legs in an immersion zone using a deterioration model. FIG. 15B is a graph of structural health condition states for offshore tubular legs in an immersion zone using time-dependent condition state probabilities. FIG. 16A is a graph of structural health condition states for offshore tubular bracings in an immersion zone using a deterioration model. FIG. 16B is a graph of structural health condition states for offshore tubular bracings in an immersion zone using time-dependent condition state probabilities.

It is observed that the jacket bracing members in the splash zone deteriorate faster than members in immersion zone due to lesser thickness compared to legs and increased corrosion rates at the splash zone. Under the exemplary model, the jacket legs reach a poor condition requiring major repair or rehabilitation in about 40 and 100 years respectively for splash and immersion zones. The bracing members reach a poor condition in 20 years and 58 years respectively for splash and immersion zones. The evolution of condition state deterioration of various members in splash and immersion zones could be further utilized in determining the global structural health condition using the criticality factors, and subsequently employed in the development of Markov-chain based model as previously explained.

Regarding prediction of Maintenance, Repair, and Rehabilitation (MRR) timing, MRR actions are based on Structural Health Index (SHI) derived from the global structural heath condition (C). The maintenance management utilizes SHI instead of percentage of condition rating. The SHI is typically calculated as follows in Equation 13:

$$S H I = 1 \times {C}_{5} + 0.75 \times {C}_{4} + 0.5 \times {C}_{3} + 0.25 \times {C}_{2} + 0 \times {C}_{1} \qquad \text{(13)}$$

Where {C5, C4,...,C1} are the percentages of the global structural health condition calculated based on Equation 2.

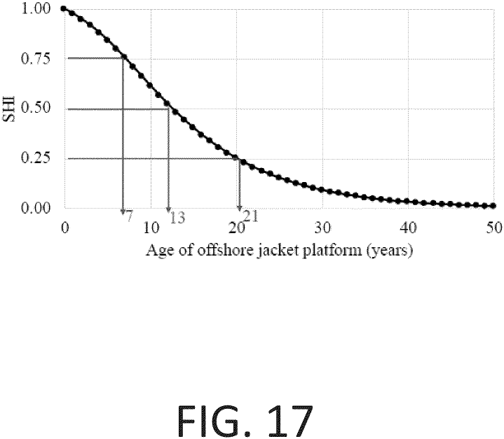

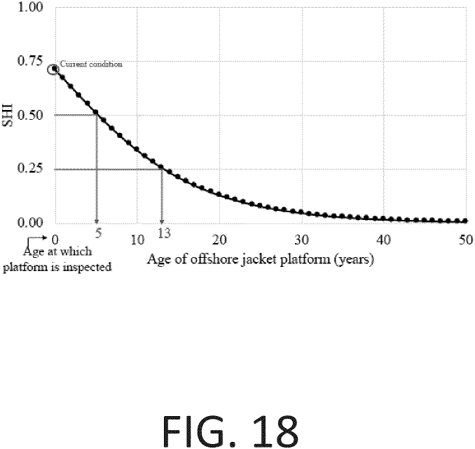

The estimated times for conducting MRR actions for a new platform and an aging platform considered in the exemplary study are shown in Table 5. FIGS. 17 and 18 show the predicted SHI values of a typical new jacket platform and an aging platform respectively in case of routine maintenance. FIG. 17 is a graph of typical SHI values of a new jacket platform and FIG. 18 is a graph of typical SHI values of an aging jacket platform.

In certain examples, in the case of a new platform (i.e., the current SHI is 1), the predicted time for minor repair is 7 years, major repair in 13 years, and need for replacement in 21 years. In the exemplary case of an aging platform with a current SHI of 0.75 (i.e., requiring minor repair), the predicted time for a major repair is 5 years and a need for replacement is in 13 years from the time of inspection. Hence, the residual service life of the aging platform considered in the exemplary study is obtained as 18 years. The approach demonstrated in this exemplary study can be easily adopted to establish MRR timing and residual service life for any given jacket platform based on the actual inspection records.

TABLE 5

PREDICTION OF MRR TIMING

| MRR actions | SHI Values | Predicted time (years) | |
|---|---|---|---|
| | | New Platform | Aging Platform |
| Do nothing | 1 | Current condition | --- |
| Minor repair | 0.75 | 7 | Current condition |
| Major repair | 0.5 | 13 | 5 |
| Replacement | 0.25 | 21 | 13 |

In this exemplary study, criticality factors are proposed based on redundancy analyses carried-out on the typical jacket platform for bracings located at various water depths. The global structural health condition of jacket computed for consecutive years is utilized to develop the average transition probability matrix (TPM) used for Markov-chain based deterioration model. The model predicts the condition of the jacket based on its current condition and the TPM. This study develops Markov-chain based models for a case study of a typical new platform and an aging platform. The evolution of condition state probabilities is also illustrated.

The second exemplary method demonstrated is stochastic-mechanistic approach to model the deterioration of the jacket members - legs and bracings in splash and immersion zones using established corrosion wastage models. This approach is proposed in case of scarcity of visual inspection records. There are two main forms of corrosion found extensively in marine structures: uniform corrosion and pitting corrosion. In one example, the evolution of condition states for jacket legs and bracings in splash and immersion zones are obtained based on 10⁶ Monte Carlo simulations. Based on the generated condition states, the deterioration model for the jacket members is developed. The exemplary modeling approach can be easily adapted and the model can be calibrated depending on expert knowledge and risk levels.

In order to predict the timing for Maintenance, Repair and Rehabilitation (MRR) actions, the evolution of Structural Health Index is computed for the jacket platform. The predicted time for MRR actions for both new platform and an aging platform are computed. The predicted time for minor repair is 7 years for the new platform. A major repair is predicted in 13 years for the new platform and 5 years for the aging platform. The need for replacement is predicted after 21 years and 13 years for new and aging platform, respectively. The residual service life of the aging platform considered in this research is 18 years. The exemplary approach demonstrated in this study can be easily adopted to establish MRR timing and residual service life for any given jacket platform based on the actual inspection records and expert knowledge.

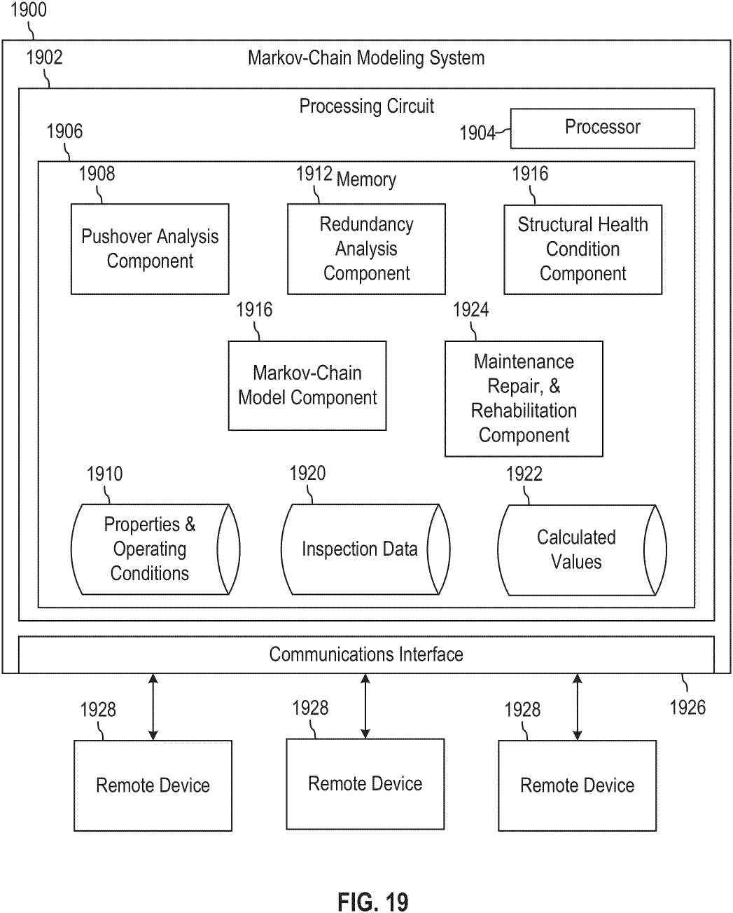

FIG. 19 shows an exemplary Markov chain modeling system 1900 is shown to include a processing circuit 1902 that includes a processor 1904 and a memory 1908. Processor 1904 can be a general-purpose processor, an ASIC, one or more FPGAs, a group of processing components, or other suitable electronic processing structures. In some embodiments, processor 1904 is configured to execute program code stored on memory 1906 to cause Markov chain modeling system 1900 to perform one or more operations, as described below in greater detail. It will be appreciated that, in embodiments where Markov chain modeling system 1900 is part of another computing device, the components of Markov chain modeling system 1900 may be shared with, or the same as, the host device.

Memory 1906 can include one or more devices (e.g., memory units, memory devices, storage devices, etc.) for storing data and/or computer code for completing and/or facilitating the various processes described in the present disclosure. In some embodiments, memory 1906 includes tangible (e.g., non-transitory), computer-readable media that stores code or instructions executable by processor 1904. Tangible, computer-readable media refers to any physical media that is capable of providing data that causes Markov chain modeling system 1900 to operate in a particular fashion. Example tangible, computer-readable media may include, but is not limited to, volatile media, non-volatile media, removable media and non-removable media implemented in any method or technology for storage of information such as computer readable instructions, data structures, program modules or other data. Accordingly, memory 1906 can include RAM, ROM, hard drive storage, temporary storage, non-volatile memory, flash memory, optical memory, or any other suitable memory for storing software objects and/or computer instructions. Memory 1906 can include database components, object code components, script components, or any other type of information structure for supporting the various activities and information structures described in the present disclosure. Memory 1906 can be communicably connected to processor 1904, such as via processing circuit 1902, and can include computer code for executing (e.g., by processor 1904) one or more processes described herein.

While shown as individual components, it will be appreciated that processor 1904 and/or memory 1906 can be implemented using a variety of different types and quantities of processors and memory. For example, processor 1904 may represent a single processing device or multiple processing devices. Similarly, memory 1906 may represent a single memory device or multiple memory devices. Additionally, in some embodiments, Markov chain modeling system 1900 may be implemented within a single computing device (e.g., one server, one housing, etc.). In other embodiments, Markov chain modeling system 1900 may be distributed across multiple servers or computers (e.g., that can exist in distributed locations). For example, Markov chain modeling system 1900 may include multiple distributed computing devices (e.g., multiple processors and/or memory devices) in communication with each other that collaborate to perform operations. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers. For example, virtualization software may be employed by Markov chain modeling system 1900 to provide the functionality of a number of servers that is not directly bound to the number of computers in Markov chain modeling system 1900.

Memory 1906 is shown to include a pushover analysis component 1908. The pushover analysis component 1908 performs finite element modeling and nonlinear static (pushover) analysis to obtain the base shear at collapse for the intact structure of a jacket platform. The pushover analysis component 1908 uses offshore jacket geometrical and material properties, and the loading conditions which are obtained for the platform of interest using the properties and operating conditions database 1910. For example, the loading conditions may include dead load, live load, and environment loads, such as wave load, and current loads for the platform of interest based on its location. For example, the loading conditions for a jacket in one location may be different than the loading conditions for a jacket in another location.

A redundancy analysis component 1912 determines criticality factors for jacket leg and bracing members of the jacket platform under various damage scenarios. The redundancy analysis component 1912 uses nonlinear static redundancy analysis. For example, a residual resistance factor is calculated for each damage scenario to determine the criticality of the leg and bracing members.

A structural health condition component 1916 leverages inspection data maintained in an inspection database 1920 to calculate the global structural health condition (C) of the jacket platform, as described above with reference to Equation (2). For example, the inspection data may indicate a condition of jacket members located at various water depths. The structural health condition component 1916 determines the global structural health condition (C) for at least two consecutive inspection periods. The calculated global structural health condition (C) may be maintained in a calculated values database 1922.

A Markov-chain model component 1916 uses the global structural health condition (C) for at least two consecutive inspection periods to determine a transition probability matrix (TPM) that characterizes the structural deterioration process. The TPM may be maintained in the calculated values database 1922. Using the TPM, the Markov-chain model component 1916 predicts the performance of the jacket platform after a selected time interval of operation, such as described above with reference to Equation (3). For example, the global structural health condition (C) of the jacket platform at a given time period in the future is predicted based on Equation (3).

A maintenance, repair, and rehabilitation (MRR) component 1924 uses predictions from the Markov-chain model component 1916 to predict the timing for maintenance, repair, and rehabilitation actions. For example, the MRR component 1924 may calculate a structural health index (SHI) derived from the global structural health conditions (C), such as described above with reference to Equation (13).

Markov chain modeling system 1900 is also shown to include a communications interface 1926 that facilitates communications between Markov chain modeling system 1900 and any external components or devices. For example, communications interface 1926 can provide means for transmitting data to, or receiving data from, one or more remote devices 1928. Accordingly, communications interface 1926 can be or can include a wired or wireless communications interface (e.g., jacks, antennas, transmitters, receivers, transceivers, wire terminals, etc.) for conducting data communications, or a combination of wired and wireless communication interfaces. In some embodiments, communications via communications interface 1926 are direct (e.g., local wired or wireless communications) or via a network (e.g., a WAN, the Internet, a cellular network, etc.). For example, communications interface 1926 may include one or more Ethernet ports for communicably coupling Markov chain modeling system 1900 to a network (e.g., the Internet). In another example, communications interface 1926 can include a WiFi transceiver for communicating via a wireless communications network. In yet another example, communications interface 1926 may include cellular or mobile phone communications transceivers.

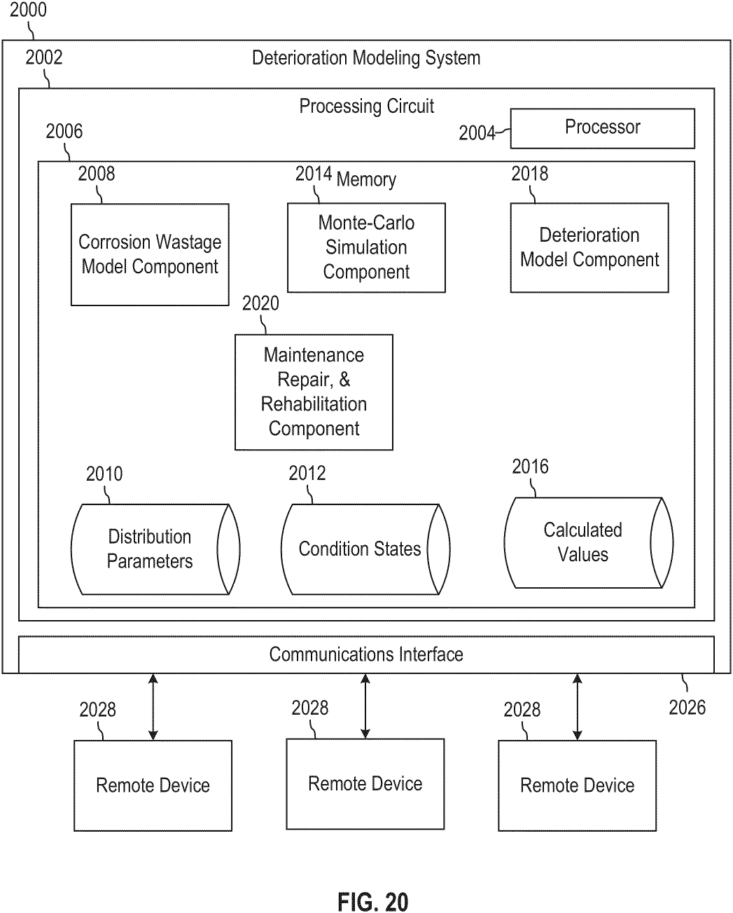

FIG. 20 shows an exemplary deterioration modeling system 2000 to include a processing circuit 2002 that includes a processor 2004 and a memory 2008. Processor 2004 can be a general-purpose processor, an ASIC, one or more FPGAs, a group of processing components, or other suitable electronic processing structures. In some embodiments, processor 2004 is configured to execute program code stored on memory 2006 to cause deterioration modeling system 2000 to perform one or more operations, as described below in greater detail. It will be appreciated that, in embodiments where deterioration modeling system 2000 is part of another computing device, the components of deterioration modeling system 2000 may be shared with, or the same as, the host device.

Memory 2006 can include one or more devices (e.g., memory units, memory devices, storage devices, etc.) for storing data and/or computer code for completing and/or facilitating the various processes described in the present disclosure. In some embodiments, memory 2006 includes tangible (e.g., non-transitory), computer-readable media that stores code or instructions executable by processor 2004. Tangible, computer-readable media refers to any physical media that is capable of providing data that causes deterioration modeling system 2000 to operate in a particular fashion. Example tangible, computer-readable media may include, but is not limited to, volatile media, non-volatile media, removable media and non-removable media implemented in any method or technology for storage of information such as computer readable instructions, data structures, program modules or other data. Accordingly, memory 2006 can include RAM, ROM, hard drive storage, temporary storage, non-volatile memory, flash memory, optical memory, or any other suitable memory for storing software objects and/or computer instructions. Memory 2006 can include database components, object code components, script components, or any other type of information structure for supporting the various activities and information structures described in the present disclosure. Memory 2006 can be communicably connected to processor 2004, such as via processing circuit 2002, and can include computer code for executing (e.g., by processor 2004) one or more processes described herein.

While shown as individual components, it will be appreciated that processor 2004 and/or memory 2006 can be implemented using a variety of different types and quantities of processors and memory. For example, processor 2004 may represent a single processing device or multiple processing devices. Similarly, memory 2006 may represent a single memory device or multiple memory devices. Additionally, in some embodiments, deterioration modeling system 2000 may be implemented within a single computing device (e.g., one server, one housing, etc.). In other embodiments, Deterioration modeling system 2000 may be distributed across multiple servers or computers (e.g., that can exist in distributed locations). For example, deterioration modeling system 2000 may include multiple distributed computing devices (e.g., multiple processors and/or memory devices) in communication with each other that collaborate to perform operations. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers. For example, virtualization software may be employed by deterioration modeling system 2000 to provide the functionality of a number of servers that is not directly bound to the number of computers in deterioration modeling system 2000.

Memory 2006 is shown to include a corrosion wastage model component 2008. The corrosion wastage model component 2008 uses different models for splash and immersion zones. The corrosion wastage model component 2008 determine the time-dependent effect of uniform corrosion and pitting corrosion. For example, the corrosion wastage model component 2008 may follow Equations (5)-(7).

Memory 2006 also includes a distribution parameters database or table 2010 and a condition states database or table 2012. The distribution parameters database 2010 includes the distribution of model parameters, such as defined in Table 2 above. The condition states database 2012 condition states of tubular members are defined based on the remaining thickness as a function of age, such as shown and described in Table 3 above.

Memory 2006 also includes a Monte-Carlo simulation component 2014 that performs Monte-Carlo simulations to derive time-dependent condition probabilities of offshore tubular members. For example, the Monte-Carlo simulation component 2014 performs simulations based on Equations (9) and (10) as described above to aggregate the probability of occurrence of each condition state for each year to be analyzed (e.g., years 1-100). In various implementations, results of the Monte-Carlo simulation component 2014 are stored in a calculated values database 2016.

Memory 2006 also includes a deterioration model component 2018 which uses the condition state probabilities calculated by the Monte-Carlo simulation component 2014 to estimate the condition state of the deterioration of legs and bracings as a function of time. For example, the deterioration model component 2018 uses the deterioration model of Equation (11) described above.

A maintenance, repair, and rehabilitation (MRR) component 2020 uses predictions from the deterioration model component 2018 to predict timing for maintenance, repair, and rehabilitation actions. For example, the MRR component 2020 may calculate a structural health index (SHI) derived from the global structural health conditions (C), such as described above with reference to Equation (13).

Deterioration modeling system 2000 is also shown to include a communications interface 2026 that facilitates communications between Deterioration modeling system 2000 and any external components or devices. For example, communications interface 2026 can provide means for transmitting data to, or receiving data from, one or more remote devices 2028. Accordingly, communications interface 2026 can be or can include a wired or wireless communications interface (e.g., jacks, antennas, transmitters, receivers, transceivers, wire terminals, etc.) for conducting data communications, or a combination of wired and wireless communication interfaces. In some embodiments, communications via communications interface 2026 are direct (e.g., local wired or wireless communications) or via a network (e.g., a WAN, the Internet, a cellular network, etc.). For example, communications interface 2026 may include one or more Ethernet ports for communicably coupling Deterioration modeling system 2000 to a network (e.g., the Internet). In another example, communications interface 2026 can include a WiFi transceiver for communicating via a wireless communications network. In yet another example, communications interface 2026 may include cellular or mobile phone communications transceivers.

While the Markov chain modeling system 1900 and the deterioration modeling system 2000 are described above as separate system, in one or more implementations, they may both be implemented in a single system.

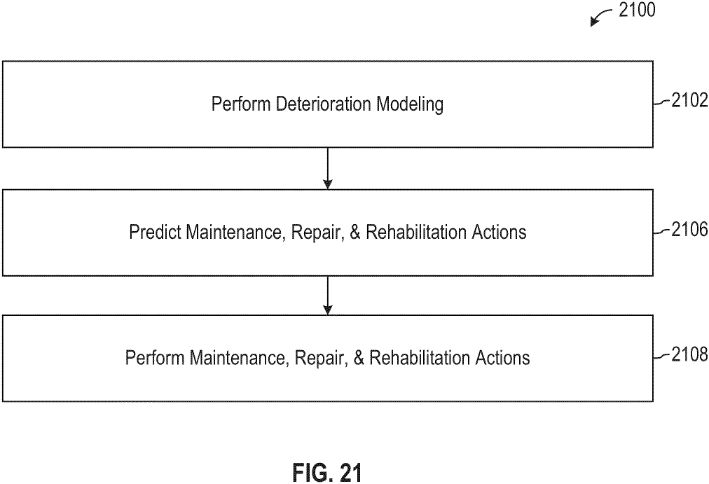

FIG. 21 is a flow chart of the methodology 2100 for predicting and performing maintenance repair, replacement, and rehabilitation actions. At 2102, deterioration modeling of a jacket platform is performed. For example, for jacket platforms with available inspection records (e.g., at least two consecutive sets of inspection data), deterioration modeling may be performed with the Markov chain modeling system 1900, as described above. However, if there is a scarcity of inspection records, the deterioration modeling may be performed with the deterioration modeling system 2000, as described above.

At 2104, predictions of timing for maintenance, repair, and rehabilitation (MRR) actions are calculated based on the deterioration modeling performed at 2102. For example, the MRR predictions may calculate a structural health index (SHI) derived from the global structural health conditions (C), such as described above with reference to Equation (13).

At 2106, one or more MRR actions are performed at the predicted time to maintain, repair, rehabilitate, or replace the jacket platform.

The construction and arrangement of the systems and methods as shown in the various exemplary implementations are illustrative only. Although only a few implementations have been described in detail in this disclosure, many modifications are possible (e.g., variations in sizes, dimensions, structures, shapes and proportions of the various elements, values of parameters, mounting arrangements, use of materials, colors, orientations, etc.). For example, the position of elements may be reversed or otherwise varied, and the nature or number of discrete elements or positions may be altered or varied. Accordingly, all such modifications are intended to be included within the scope of the present disclosure. The order or sequence of any process or method steps may be varied or re-sequenced according to alternative implementations. Other substitutions, modifications, changes, and omissions may be made in the design, operating conditions, and arrangement of the exemplary implementations without departing from the scope of the present disclosure.

The present disclosure contemplates methods, systems, and program products on any machine-readable media for accomplishing various operations. The implementations of the present disclosure may be implemented using existing computer processors, or by a special purpose computer processor for an appropriate system, incorporated for this or another purpose, or by a hardwired system. Implementations within the scope of the present disclosure include program products including machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures, and which can be accessed by a general purpose or special purpose computer or other machine with a processor.

When information is transferred or provided over a network or another communications connection (either hardwired, wireless, or a combination of hardwired or wireless) to a machine, the machine properly views the connection as a machine-readable medium. Thus, any such connection is properly termed a machine-readable medium. Combinations of the above are also included within the scope of machine-readable media. Machine-executable instructions include, for example, instructions and data which cause a general-purpose computer, special purpose computer, or special purpose processing machines to perform a certain function or group of functions.

Although the figures show a specific order of method steps, the order of the steps may differ from what is depicted. Also, two or more steps may be performed concurrently or with partial concurrence. Such variation will depend on the software and hardware systems chosen and on designer choice. All such variations are within the scope of the disclosure. Likewise, software implementations could be accomplished with standard programming techniques with rule-based logic and other logic to accomplish the various connection steps, processing steps, comparison steps and decision steps.

It is to be understood that the methods and systems are not limited to specific synthetic methods, specific components, or to particular compositions. It is also to be understood that the terminology used herein is for the purpose of describing particular implementations only and is not intended to be limiting.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. It is understood that combinations, subsets, interactions, groups, etc. of these components are disclosed, and while specific reference of each various individual and collective combination and permutation of these components may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of implementations of the disclosed methods.

While the disclosure has been described in detail and with reference to specific examples thereof, it will be apparent to one skilled in the art that various changes and modifications can be made therein without departing from the spirit and scope thereof.

### REFERENCES

Aeran, A., Siriwardane, S.C., Mikkelsen, O. and Langen, I., A framework to assess structural integrity of ageing offshore jacket structures for life extension. Marine Structures, vol. 56, pp.237-259, (2017).

Busby, R. F., “Underwater inspection/testing/monitoring of offshore structures.” Ocean Engineering 6, no. 4 pp.355- 491, (1979).

Guédé, F., Risk-based structural integrity management for offshore jacket platforms. Marine Structures, vol. 63, pp.444-46, (2019).

Bai, Yong., Kim, Younghoon., Yan, Hui-bin., Song, Xiaofeng., and Jiang, Hua., “Reassessment of the jacket structure due to uniform corrosion damage.” Ships and Offshore Structures 11, no. 1, pp.105-112, (2016).

Srikanth, Ishwarya., and Arockiasamy, Madasamy., “Deterioration models for prediction of remaining useful life of timber and concrete bridges-a review.” Journal of traffic and transportation engineering (English edition), (2020).

Srikanth, Ishwarya., and Arockiasamy, Madasamy. “Integrated Probabilistic-Mechanistic Deterioration Modeling for Preventive Maintenance of Aging Fixed Offshore Jacket-Type Platforms.” In ASME 2020 39th International Conference on Ocean, Offshore and Arctic Engineering. American Society of Mechanical Engineers Digital Collection, (2020).

Price, S., and Figueira, R., Corrosion protection systems and fatigue corrosion in offshore wind structures: current status and future perspectives. Coatings, 7(2), p.25, (2017).

Melchers, R.E., Probabilistic modelling of marine corrosion of steel specimens. In: Proceedings of the 5th international offshore and polar engineering conference; Hague, The Netherlands, (1995).

PMB Engineering, Inc., Benchmark Ultimate Strength Analysis - Sample Application of API RP 2A, Section 17., (1997).

Senthil, R., S. Ishwarya., and M. Arockiasamy., “Nonlinear dynamic analysis of jacket-type offshore platform and optimization of leg batter.” In Engineering Challenges for Sustainable Future, vol. 45, no. 49, pp. 45-49. ROUTLEDGE in association with GSE Research, (2016).

Srikanth, Ishwarya., Arockiasamy, M., and Senthil, R., Inelastic nonlinear pushover analysis of fixed Jacket-type offshore platform with different bracing systems considering soil- structure interaction. Journal of Shipping and Ocean Engineering 6, pp.241-254, (2016).

Srikanth, Ishwarya., Nonlinear Static and Dynamic Analyses of Jacket-type Offshore Platform. Master’s thesis, Anna University, Chennai, India.,

.,10.13140/RG.2.2.22187.08486.

LRFD, API RP2A. “Recommended Practice for Planning Designing and Constructing Fixed Offshore Platforms--LRFD.” (1993).

Veritas, Det Norske. “Rules for the Design.” Construction and Inspection of Fixed Offshore Structures (1977).

NORSOK standard N-006. Assessment of Structural Integrity for Existing Offshore Load- Bearing Structures. 1st ed. Norway, (2009).

What is claimed is:

1. A method of determining an offshore jacket platform’s condition comprising:
(a) determining a geometry of the offshore jacket platform;
(b) determining the offshore jacket platform’s material composition;
(c) determining a plurality of loads acting upon the offshore jacket platform;
(d) obtaining a base shear at collapse for the offshore jacket platform when the offshore jacket platform is intact, wherein the base shear at collapse is determined from the geometry, the material composition, and the plurality of loads acting upon the offshore jacket platform;
(e) calculating a residual resistance factor;
(f) determining a criticality factor for each of a plurality of members on the offshore jacket platform;
(g) determining a structural health condition state for the offshore jacket platform;
(h) determining the probability of deterioration of the offshore jacket platform; and
(i) modeling a rate of deterioration of the offshore jacket platform.

2. The method of claim 1, wherein the plurality of loads comprises dead load, wave load, and current load on the offshore jacket platform.

3. The method of claim 1, wherein step (d) further comprises performing a nonlinear static pushover analysis using variables comprising the geometry, the material composition, and the plurality of loads acting upon the offshore jacket platform.

4. The method of claim 1, wherein the residual resistance factor is calculated by dividing the ultimate resistance of the offshore jacket platform with any damage by the ultimate resistance of an undamaged offshore jacket platform.

5. The method of claim 1, wherein the criticality factor corresponds to the residual resistance factor and the criticality factor is assigned a value selected from the group consisting of:
(a) 1 when the residual resistance factor is less than or equal to 0.2;
(b) 0.8 when the residual resistance factor is greater than 0.2 and less than or equal to 0.4;
(c) 0.6 when the residual resistance factor is greater than 0.4 and less than or equal to 0.6;
(d) 0.4 when the residual resistance factor is greater than 0.6 and less than or equal to 0.8; and
(e) 0.2 when the residual resistance factor is greater than 0.8 and less than 1.

6. The method of claim 5, wherein the criticality factor is assigned a failure consequence, wherein the failure consequence is selected from the group consisting of: very serious, serious, not serious, local effect, and does not affect,
wherein very serious corresponds to a criticality factor of 1, serious corresponds to a criticality factor of 0.8, not serious corresponds to a criticality factor of 0.6, local effect corresponds to a criticality factor of 0.4, and does not affect corresponds to a criticality factor of 0.2.

7. The method of claim 1, wherein the probability of deterioration is determined by multiplying a transpose of a transition probability matrix by an initial condition vector of the offshore jacket platform by a vector of at least one structural health condition state.

8. The method of claim 1, wherein step (i) further comprises using a Markov chain stochastic model.

9. A method of determining an offshore jacket platform’s condition comprising:
(a) selecting a corrosion wastage model for splash zones and immersion zones;
(b) identifying distribution parameters for a remaining thickness of each of a plurality of legs and a plurality of bracings of the offshore jacket platform;
(c) determining a structural health condition state for each of a plurality of members on the offshore jacket platform;
(d) aggregating probable structural health condition states for a predetermined number of years; and
(e) modeling a rate of deterioration of the offshore jacket platform.

10. The method of claim 9, wherein the corrosion wastage model is a uniform corrosion wastage model.

11. The method of claim 9, wherein the corrosion wastage model is a pitting corrosion wastage model.

12. The method of claim 9, wherein the distribution parameters of the legs and bracings is assumed to be of a normal distribution, wherein the normal distribution of the legs is calculated by an equation comprising:
$${f}_{l} \left({t}_{l} \left|30 , 10\right)\right) = \frac{1}{10 \times \sqrt{2 π}} \times {e}^{\frac{{\left(x - 30\right)}^{3}}{2 \times {10}^{2}}} ; \text{and}$$
the normal distribution of the bracings is calculated by an equation comprising:
$${f}_{b} \left({t}_{l} \left|15 , 5\right)\right) = \frac{1}{5 \sqrt{2 π}} \times {e}^{\frac{{\left(x - 15\right)}^{2}}{2 \times {5}^{3}}} ;$$
wherein ƒ₁ is the distribution parameter for the legs, ƒ_{b} is the distribution parameter for the bracings, tᵢ is initial thickness of the leg or bracing, and e is a mathematical constant.

13. The method of claim 9, wherein the structural health condition state is determined from the remaining thickness of each of the plurality of legs and the plurality of bracings.

14. The method of claim 9, wherein the structural health condition state is assigned a value selected from the group consisting of CS5, CS4, CS3, CS2, and CS1;
wherein CS5 indicates very good condition of the offshore jacket platform, CS4 indicates good condition of the offshore jacket platform, CS3 indicates fair condition of the offshore jacket platform, CS2 indicates poor condition of the offshore jacket platform, and CS1 indicates very poor condition of the offshore jacket platform.

15. The method of claim 9, wherein the predetermined number of years in step (d) is from 1 to 100 years.

16. The method of claim 9, wherein step (e) further comprises performing a predetermined number of Monte Carlo Simulations.

17. The method of claim 16, wherein the predetermined number of Monte Carlo simulations is from 100 to 1,000,000 Monte Carlo simulations.

18. The method of claim 16, wherein each Monte Carlo simulation is performed by:
a) defining a plurality of input variables;
b) defining a plurality of parameters;
c) generating random numbers from a probability distribution defined for each input variable;
d) deterministically computing each of a plurality of runs of randomly generated input parameters; and
e) analyzing results to obtain probabilities of different outcomes of deterioration.

19. The method of claim 18, wherein the plurality of input variables comprises a condition state probability and a vector of at least one condition state.
